(19) United States
(12) Patent Application Publication
(10) Pub. No.: US 2025/0208950 A1
(43) Pub. Date: Jun. 26, 2025

(54) MEMORY MAINTENANCE OPERATIONS

(71) Applicant: Micron Technology, Inc., Boise, ID (US)

(72) Inventors: Daniele Balluchi, Cernusco Sul Naviglio (IT); Marco Sforzin, Cernusco Sul Naviglio (IT); Paolo Amato, Treviglio (IT)

(21) Appl. No.: 18/791,126

(22) Filed: Jul. 31, 2024

Related U.S. Application Data
(60) Provisional application No. 63/613,997, filed on Dec. 22, 2023.

(51) Int. Cl. G06F 11/10

(52) U.S. Cl. CPC G06F 11/106; G06F 11/1016; G06F 11/1068

(57) ABSTRACT

The present disclosure includes apparatuses, methods, and systems for memory maintenance operations. An embodiment includes a memory having a plurality of groups of memory cells, wherein one of the plurality of groups of memory cells does not have data stored therein and all other ones of the plurality of groups of memory cells have data stored therein, and a controller coupled to the memory and having circuitry configured to determine one of the plurality of groups of memory cells that has data stored therein is a bad group of memory cells, recover the data stored in the bad group of memory cells, program the recovered data to the one of the plurality of groups of memory cells that does not have data stored therein, and retire the bad group of memory cells.

### PRIORITY INFORMATION

This application claims the benefit of U.S. Provisional Application No. 63/613,997, filed on Dec. 22, 2023, the contents of which are incorporated herein by reference.

### TECHNICAL FIELD

The present disclosure relates generally to semiconductor memory and methods, and more particularly, to memory maintenance operations.

### BACKGROUND

Memory devices are typically provided as internal, semiconductor, integrated circuits and/or external removable devices in computers or other electronic devices. There are many different types of memory including volatile and non-volatile memory. Volatile memory can require power to maintain its data and can include random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), ferroelectric random access memory (FeRAM), and resistance variable memory such as phase change random access memory (PCRAM), resistive random access memory (RRAM), magnetic random access memory (MRAM), and programmable conductive memory, among others.

Memory devices can be utilized as volatile and non-volatile memory for a wide range of electronic applications in need of high memory densities, high reliability, and low power consumption. Non-volatile memory may be used in, for example, personal computers, portable memory sticks, solid state drives (SSDs), digital cameras, cellular telephones, portable music players such as MP3 players, and movie players, among other electronic devices.

Memory devices may be coupled to a host (e.g., a host computing device) to store data, commands, and/or instructions for use by the host while the computer or electronic system is operating. For example, data, commands, and/or instructions can be transferred between the host and the memory device(s) during operation of a computing or other electronic system. A controller may be used to manage the transfer of data, commands, and/or instructions between the host and the memory devices.

### BRIEF DESCRIPTION OF THE DRAWINGS

FIG. 1 illustrates a diagram of a portion of a memory array having a number of physical blocks in accordance with an embodiment of the present disclosure.

FIG. 2 is a block diagram of a computing system in accordance with an embodiment of the present disclosure.

FIGS. 3A-3D are tables illustrating a conceptual example of memory maintenance operations performed in accordance with an embodiment of the present disclosure.

### DETAILED DESCRIPTION

The present disclosure includes apparatuses, methods, and systems for memory maintenance operations. An embodiment includes a memory having a plurality of groups of memory cells, wherein one of the plurality of groups of memory cells does not have data stored therein and all other ones of the plurality of groups of memory cells have data stored therein, and a controller coupled to the memory and having circuitry configured to determine one of the plurality of groups of memory cells that has data stored therein is a bad group of memory cells, recover the data stored in the bad group of memory cells, program the recovered data to the one of the plurality of groups of memory cells that does not have data stored therein, and retire the bad group of memory cells.

Memory cells may undergo wear as they are sensed and/or programmed throughout the lifetime of a memory device. Such wear can eventually cause the memory cells to become unreliable for storing and/or retrieving data, which in turn can reduce the reliability and/or performance of the memory device.

In previous approaches, the host of a memory system that utilizes a compute express line (CXL) protocol can retire groups (e.g., pages) of memory cells that become unreliable (e.g., due to wear) during the lifetime of the memory devices of the system, to attempt to prevent the entire system from becoming unreliable and failing. Further, in such previous approaches, the memory devices of the system can implement (e.g., on-die) a wear leveling operation (e.g., scheme) to relocate (e.g., remap) data currently being stored in one physical location (e.g., one physical page) of a memory device to another physical location (e.g., another physical page) of the memory device, to attempt to more uniformly distribute such wear across the memory devices.

Such approaches, however, may not be effective at increasing the efficiency and reliability of the memory system. For example, a single unreliable (e.g., bad) page may generate several data errors when read and mapped to different locations (e.g., different logical addresses), which may cause applications being run by the memory system to be killed. Further, the location (e.g., address) mapping of a bad page may change during the lifetime of the memory system.

Embodiments of the present disclosure, however, can increase the efficiency, reliability and/or performance of a memory system that utilizes a CXL protocol, and therefore extend the lifetime of the memory system, by moving maintenance (e.g., wear leveling) operations from the memory devices of the system to the controller of the system. For example, moving the maintenance operations from the memory devices to the controller can result in lower latency for the system, since the memory devices do not have to have address remapping. Further, the controller can retire bad pages without exposing the bad pages to the host of the system, which can reduce the amount of errors returned to the host and increase the lifetime of the memory devices.

As used herein, “a”, “an”, or “a number of” can refer to one or more of something, and “a plurality of” can refer to two or more such things. For example, a memory device can refer to one or more memory devices, and a plurality of memory devices can refer to two or more memory devices. Additionally, the designators “N”, “M”, “R”, “S”, and “B”, as used herein, particularly with respect to reference numerals in the drawings, indicates that a number of the particular feature so designated can be included with a number of embodiments of the present disclosure

The figures herein follow a numbering convention in which the first digit or digits correspond to the drawing figure number and the remaining digits identify an element or component in the drawing. Similar elements or components between different figures may be identified by the use of similar digits.

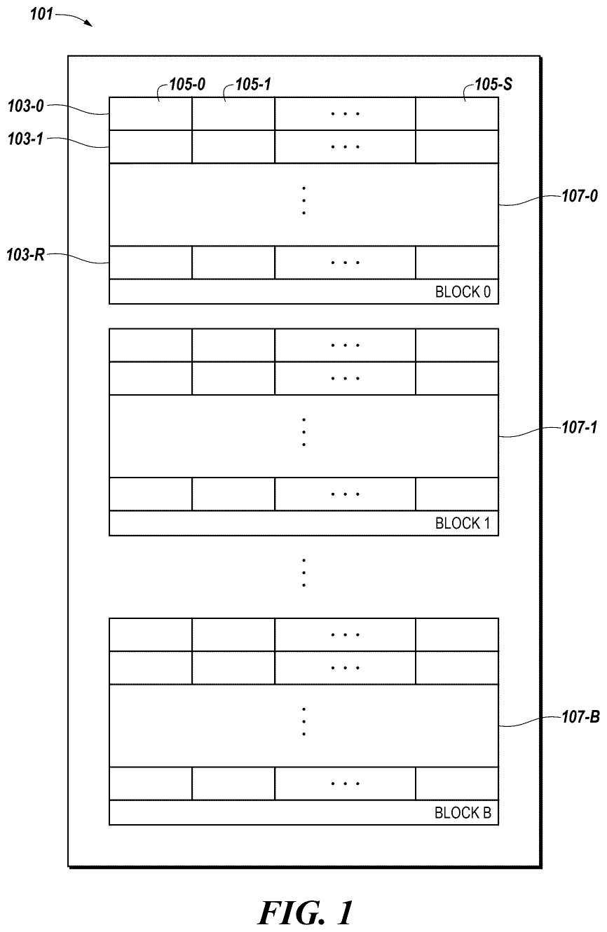

FIG. 1 illustrates a diagram of a portion of a memory array 101 having a number of physical blocks in accordance with an embodiment of the present disclosure. Memory array 101 can be, for example, a ferroelectric RAM (FeRAM) memory array. However, embodiments of the present disclosure are not so limited. For instance, memory array 101 can be a DRAM array, a NAND flash memory array, or a resistance variable memory array such as a PCRAM, RRAM, or spin torque transfer (STT) array, among others. Further, although not shown in FIG. 1, memory array 101 can be located on a particular semiconductor die along with various peripheral circuitry associated with the operation thereof.

As shown in FIG. 1, memory array 101 has a number of physical blocks 107-0 (BLOCK 0), 107-1 (BLOCK 1), . . . , 107-B (BLOCK B) of memory cells (e.g., ferroelectric memory cells). The memory cells can be single level cells and/or multilevel cells such as, for instance, two level cells, triple level cells (TLCs) or quadruple level cells (QLCs). As an example, the number of physical blocks (e.g., banks) in memory array 101 may be 32 blocks, 64 blocks, 128 blocks, 512 blocks, or 1,024 blocks, but embodiments are not limited to a particular power of two or to any particular number of physical blocks in memory array 101.

A number of physical blocks of memory cells (e.g., blocks 107-0, 107-1, . . . , 107-B) can be included in a plane of memory cells, and a number of planes of memory cells can be included on a die. For instance, in the example shown in FIG. 1, each physical block 107-0, 107-1, . . . , 107-B can be part of a single die. That is, the portion of memory array 101 illustrated in FIG. 1 can be a die of memory cells.

As shown in FIG. 1, each physical block 107-0, 107-1, . . . , 107-B includes a number of physical rows (e.g., 103-0, 103-1, . . . , 103-R) of memory cells coupled to access lines (e.g., word lines). As an example, the number of rows (e.g., word lines) in each physical block can be 2,097,152, but embodiments are not limited to a particular number of rows 103-0, 103-1, . . . , 103-R per physical block. Further, although not shown in FIG. 1, the memory cells can be coupled to sense lines (e.g., data lines and/or digit lines).

As one of ordinary skill in the art will appreciate, each row 103-0, 103-1, . . . , 103-R can include a number of pages of memory cells (e.g., physical pages). A physical page refers to a unit of programming and/or sensing (e.g., a number of memory cells that are programmed and/or sensed together as a functional group). In the embodiment shown in FIG. 1, each row 103-0, 103-1, . . . , 103-R comprises one physical page of memory cells. However, embodiments of the present disclosure are not so limited. For instance, in an embodiment, each row can comprise multiple physical pages of memory cells (e.g., one or more even pages of memory cells coupled to even-numbered bit lines, and one or more odd pages of memory cells coupled to odd numbered bit lines). Additionally, for embodiments including multilevel cells, a physical page of memory cells can store multiple pages (e.g., logical pages) of data (e.g., an upper page of data and a lower page of data, with each cell in a physical page storing one or more bits towards an upper page of data and one or more bits towards a lower page of data).

As shown in FIG. 1, a page of memory cells can comprise a number of physical sectors 105-0, 105-1, . . . , 105-S(e.g., subsets of memory cells). Each physical sector 105-0, 105-1, . . . , 105-S of cells can store a number of logical sectors of data. Additionally, each logical sector of data can correspond to a portion of a particular page of data. As an example, a first logical sector of data stored in a particular physical sector can correspond to a logical sector corresponding to a first page of data, and a second logical sector of data stored in the particular physical sector can correspond to a second page of data. Each physical sector 105-0, 105-1, . . . , 105-S, can store system and/or user data, and/or can include overhead data, such as error correction code (ECC) data, logical block address (LBA) data, and metadata.

Logical block addressing is a scheme that can be used by a host for identifying a logical sector of data. For example, each logical sector can correspond to a unique logical block address (LBA). Additionally, an LBA may also correspond (e.g., dynamically map) to a physical address, such as a physical block address (PBA), that may indicate the physical location of that logical sector of data in the memory. A logical sector of data can be a number of bytes of data (e.g., 256 bytes, 512 bytes, 1,024 bytes, or 4,096 bytes). However, embodiments are not limited to these examples.

It is noted that other configurations for the physical blocks 107-0, 107-1, . . . , 107-B, rows 103-0, 103-1, . . . , 103-R, sectors 105-0, 105-1, . . . , 105-S, and pages are possible. For example, rows 103-0, 103-1, . . . , 103-R of physical blocks 107-0, 107-1, . . . , 107-B can each store data corresponding to a single logical sector which can include, for example, more or less than 512 bytes of data.

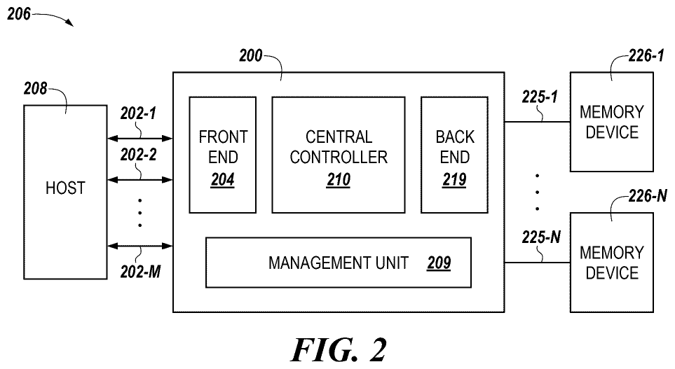

FIG. 2 is a block diagram of a computing system 206 in accordance with an embodiment of the present disclosure. The computing system 206 can include a controller 200 having a front end portion 204, a central controller portion 210, a back end portion 219, and a management unit 209. The computing system 206 can include a host 208 and memory devices 226-1, . . . , 226-N coupled to the controller 200.

The front end portion 204 includes an interface and interface management circuitry to couple the controller 200 to the host 208 through input/output (I/O) lanes 202-1, 202-2, . . . , 202-M and circuitry to manage the I/O lanes 202. There can be any quantity of I/O lanes 202, such as eight, sixteen, or another quantity of I/O lanes 202. In some embodiments, the I/O lanes 202 can be configured as a single port.

In some embodiments, the controller 200 can be a compute express link (CXL) compliant memory controller. The host interface (e.g., the front end portion 204) is coupled to the host 208 and can be managed with CXL protocols.

CXL is a high-speed central processing unit (CPU)-to-device and CPU-to-memory interconnect designed to accelerate next-generation data center performance. CXL technology maintains memory coherency between the CPU memory space and memory on attached devices, which allows resource sharing for higher performance, reduced software stack complexity, and lower overall system cost. CXL is designed to be an industry open standard interface for high-speed communications, as accelerators are increasingly used to complement CPUs in support of emerging applications such as artificial intelligence and machine learning. CXL technology is built on the PCIe infrastructure, leveraging PCIe physical and electrical interfaces to provide advanced protocol in areas such as input/output (I/O) protocol, memory protocol (e.g., initially allowing a host to share memory with an accelerator), and coherency interface. As an example, the interface of the front end 204 can be a PCIe 5.0 or 6.0 interface coupled to the I/O lanes 202. In some embodiments, the controller 200 can receive access requests involving the memory devices 226 via the PCIe 5.0 or 6.0 interface according to a CXL protocol.

The central controller portion 210 can include and/or be referred to as data management circuitry. The central controller portion 210 can control, in response to receiving a request from the host 208, performance of a memory operation. Examples of the memory operation include a read operation to read data from a memory device 226 or a write operation to write data to a memory device 226.

The central controller portion 210 can generate error detection information and/or error recovery information based on data received from the host 208. The central controller portion 210 can perform error detection operations and/or error recovery operations on data received from the host 208 or from the memory devices 226. An example of an error detection operation is a cyclic redundancy check (CRC) operation. CRC may be referred to as algebraic error detection. CRC can include the use of a check value resulting from an algebraic calculation using the data to be protected. CRC can detect accidental changes to data by comparing a check value stored in association with the data to the check value calculated based on the data. An example of an error correction operation is an error correction code (ECC) operation. ECC encoding refers to encoding data by adding redundant bits to the data. ECC decoding refers to examining the ECC encoded data to check for any errors in the data. In general, the ECC can not only detect the error but also can correct a subset of the errors it is able to detect. The central controller portion 210 can also perform maintenance (e.g., wear leveling) operations on data stored in memory devices 226, and retire bad groups of memory cells in memory devices 226, as will be further described herein.

The back end portion 219 can include a media controller and a physical (PHY) layer that couples the controller 200 to the memory devices 226. As used herein, the term “PHY layer” generally refers to the physical layer in the Open Systems Interconnection (OSI) model of a computing system. The PHY layer may be the first (e.g., lowest) layer of the OSI model and can be used transfer data over a physical data transmission medium. In some embodiments, the physical data transmission medium can include channels 225-1, . . . , 225-N. The channels 225 can include various types of data buses, such as a four-pin data bus (e.g., data input/output (DQ) bus) and a one-pin data mask inversion (DMI) bus, among other possible buses.

The memory devices 226 can be various/different types of memory devices that can each include a number of memory arrays 101 previously described in connection with FIG. 1. For instance, memory devices 226 can each include a plurality of groups of memory cells, such as a plurality of pages (e.g., physical pages) of memory cells, as previously described in connection with FIG. 1. One (e.g., only a single one) of the groups of memory cells of the memory device may not have data stored therein. For instance, one of the groups of memory cells may be reserved as a spare page. All the other ones of the plurality of groups of memory cells of the memory device may have data (e.g. user data) stored therein.

In some embodiments, a different respective physical address can be associated with each respective one of the plurality of groups of memory cells of a memory device 226. For example, the physical address associated with each respective one of the plurality of groups of memory cells can correspond to a different pin of the memory device 226 (e.g., a first address can correspond to a first pin, a second address can correspond to a second pin, etc.). Further, the group of memory cells of the memory device that does not have data stored therein (e.g., the spare page) can be addressable. For instance, a logical address can be mapped to the physical address associated with that group, as will be further described herein.

In some embodiments, host 208 can have a different respective logical address associated with all but one of the plurality of groups of memory cells of a memory device 226 that have data stored therein (e.g., one of the groups of memory cells that has data stored therein does not have a logical address associated therewith). Further, host 208 may not have a logical address associated with the group of memory cells of the memory device that does not have data stored therein.

As an example, the memory devices 226 can be ferroelectric RAM (FeRAM) devices that includes ferroelectric capacitors that can exhibit hysteresis characteristics. As an example, a FeRAM device can include ferroelectric capacitors and can perform bit storage based on an amount of voltage or charge applied thereto. In such examples, relatively small and relatively large voltages allow the ferroelectric RAM device to exhibit characteristics similar to normal dielectric materials (e.g., dielectric materials that have a relatively high dielectric constant) but at various voltages between such relatively small and large voltages the ferroelectric RAM device can exhibit a polarization reversal that yields non-linear dielectric behavior.

Embodiments of the present disclosure, however, are not so limited, and memory devices 226 can be other types of non-volatile memory devices, such as NAND or NOR flash memory devices, or resistance variable memory devices such as PCRAM, RRAM, or spin torque transfer (STT) memory devices, among others. In another example, the memory devices 226 can be dynamic random access memory (DRAM) operated according to a protocol such as low-power double data rate (LPDDRx), which may be referred to herein as LPDDRx DRAM devices, LPDDRx memory, etc. The “x” in LPDDRx refers to any of a number of generations of the protocol (e.g., LPDDR5).

In some embodiments, the controller 200 can include a management unit 209 to initialize, configure, and/or monitor characteristics of the controller 200. The management unit 209 can include an I/O bus to manage out-of-band data and/or commands, a management unit controller to execute instructions associated with initializing, configuring, and/or monitoring the characteristics of the memory controller, and a management unit memory to store data associated with initializing, configuring, and/or monitoring the characteristics of the controller 200. As used herein, the term “out-of-band” generally refers to a transmission medium that is different from a primary transmission medium of a network. For example, out-of-band data and/or commands can be data and/or commands transferred to a network using a different transmission medium than the transmission medium used to transfer data within the network.

Controller 200 (e.g., central controller portion 210) can perform maintenance (e.g., wear leveling) operations on data (e.g., user data) stored in memory devices 226, and retire bad groups of memory cells in memory devices 226. For example, controller 200 can determine that one of the plurality of groups of memory cells of a memory device 226 that has data stored therein is a bad group (e.g., a bad page) of memory cells. As used herein a “bad group” of memory cells can refer to a group (e.g., page) of memory cells that is not reliable for storing and/or retrieving data (e.g. user data) because it is physically damaged or corrupted. Controller 200 can determine the bad group of memory cells, for example, during a scrub operation being performed on the memory device 226 (e.g., on the groups of memory cells of memory device 226). As used herein, the term “scrub operation” can refer to an operation to correct, if any, an error within data values stored in a group of memory cells, and rewrite the error-corrected data pattern to the group of memory cells.

Controller 200 can recover the data stored in the bad group of memory cells by performing an error correction operation on the data stored in the bad group of memory cells. For example, controller 200 can recover the data by performing a redundant array of independent disks (RAID) operation on the data stored in the bad group of memory cells. The RAID operation can be performed, for instance, as part of a RAID data protection and recovery scheme, which can divide and/or replicate the data stored in a group of memory cells among multiple memory devices (e.g., across a stripe of memory devices), and subsequently recover lost data using the data in the stripe. RAID, as used herein, is an umbrella term for computer information (e.g., data) storage schemes that divide and/or replicate (e.g., mirror) information among multiple pages of multiple memory devices and/or components, for instance, in order to help protect the data stored therein. The multiple memory devices and/or components in a RAID array may appear to a user and the operating system of a computer as a single memory device (e.g., disk). RAID can include striping (e.g., splitting) information so that different portions of the information are stored on different pages of different memory devices and/or components. The portions of the more than one device or component that store the split data are collectively referred to as a stripe. In contrast, RAID can also include mirroring, which can include storing duplicate copies of data on more than one page of more than one device or component. As an example of the former, write data can be striped across N−1 of N memory devices and/or components, where error information can be stored in an Nth memory device or component. A RAID stripe can include (e.g., be a combination of) user data and parity data. The parity data of the RAID stripe can include error protection data that can be used to protect user data stored in the memory against defects and/or errors that may occur during operation of the memory. For example, the RAID stripe can protect user data stored in the memory against defects and/or errors that may occur during operation of the memory, and can therefore provide protection against a failure of the memory.

Controller 200 can program the data recovered from the bad group of memory cells to the group of memory cells of the memory device 226 that does not have data stored therein (e.g., such that the recovered data is stored in the spare page of the memory device), and retire the bad group of memory cells. Retiring the bad group of memory cells can include and/or refer to no longer using the bad group of memory cells to store data (e.g., no longer programming data to, or sensing data from, the bad group). Controller 200 can map the logical address of host 208 that is associated with the bad group of memory cells to the physical address associated with the group of memory cells to which the recovered data was programmed (e.g., to the page that was previously the spare page), such that the bad group of memory cells no longer has a logical address associated therewith.

Controller 200 can then copy the data stored in one of the plurality of groups of memory cells of the memory device 226 to another one of the plurality of groups of memory cells of the memory device 226 that has data stored therein (e.g., the group that does not have a logical address associated therewith), erase the group of memory cells from which the data was copied, and map the logical address associated with the group of memory cells from which the data was copied to the group of memory cells to which the data is copied. This erased group of memory cells can become the spare page for use in a subsequent maintenance operation and/or bad group retirement. In some examples (e.g., in which the memory cells of the memory device 226 are bit alterable), the erase operation may be optional.

If maintenance (e.g., wear leveling) operations are performed on data stored in memory devices 226, controller 200 can disable on-die wear leveling operations and/or random data scrambling operations in memory devices 226. Controller 200 can disable these operations using, for example, a configuration data bit in memory devices 226.

The below example algorithm can be used by controller 200 (e.g., central controller portion 210) for performing wear leveling operations as described herein. The following parameters are used in the algorithm:
N+1 physical locations, from 0 to N
   P: physical address. P∈{0, . . . , N}
   L: logical address. L∈{0, . . . , N−1}
S: start address. S is a physical address, S∈{0, . . . , N}
G: gap address. G is a physical address, G∈{0, . . . , N}
   The pair S, G defines a logical to physical map P=f_{S,G}(L). The map f_{S,G} is defined by the rule:

$$P = {f}_{S , G} ( L ) = {( S + L + U [ S + L - G - ( N + 1 ) u ( S - G ) ] )}_{mod N + 1}$$

where U [.] is the step function (U[i]=1 if i≥0, U[i]=0 if i<0). At the beginning (t=0) S and G are set to 0 and N respectively:

S(0)=0, G(0)=N

At each wear leveling operation, G decreases (cyclically) its value. Therefore:

$$G ( t + 1 ) = {( G ( t ) - 1 )}_{mod N + 1}$$

and if:

$$G ( t + 1 ) = S ( t )$$

then:

$$S ( t + 1 ) = {( S ( t ) + 1 )}_{mod N + 1}$$

otherwise:

$$S ( t + 1 ) = S ( t )$$

Each time G is decreased, the data D in the location corresponding to the new G is moved to the old G location:

D_{G(t)}=D_{G(t+1)}

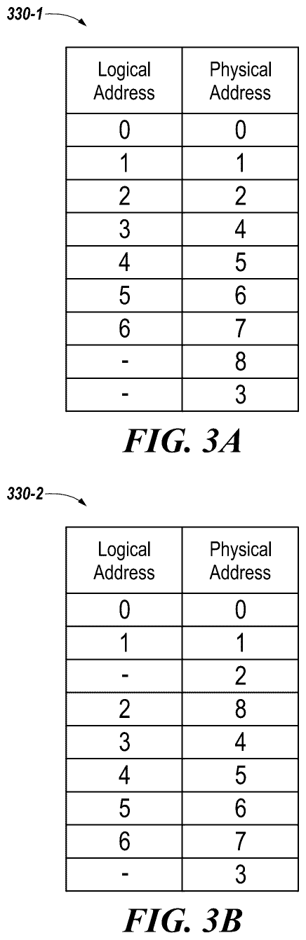

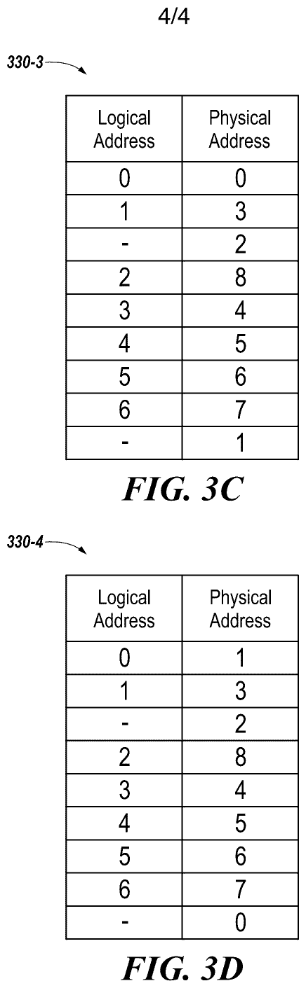

FIGS. 3A-3D are tables 330-1, 330-2, 330-3, and 330-4 illustrating a conceptual example of memory maintenance operations performed in accordance with an embodiment of the present disclosure. The memory maintenance operations can be performed by, for example, controller 200 on a memory device 226 as previously described herein (e.g., in connection with FIG. 2).

For example, the memory device can include a plurality of groups (e.g., pages) of memory cells. For instance, in the example shown in table 330-1 in FIG. 3A, the memory device includes nine groups of memory cells. However, embodiments of the present disclosure are not limited to a specific quantity of memory cell groups.

A different respective physical address can be associated with each respective one of the plurality of groups of memory cells, as previously described herein. For instance, in the example shown in table 330-1 in FIG. 3A, a first group of memory cells has a physical address of 0, a second group of memory cells has a physical address of 1, a third group of memory cells has a physical address of 2, a fourth group of memory cells has a physical address of 3, a fifth group of memory cells has a physical address of 4, a sixth group of memory cells has a physical address of 5, a seventh group of memory cells has a physical address of 6, an eighth group of memory cells has a physical address of 7, and a ninth group of memory cells has a physical address of 8.

One of the groups of memory cells of the memory device may not have data stored therein (e.g., may be a spare group), and all the other ones of the plurality of groups of memory cells of the memory device may have data (e.g. user data) stored therein, as previously described herein. For instance, in the example shown in table 330-1 in FIG. 3A, the ninth group of memory cells (e.g., the group with a physical address of 8) is the spare group.

Further, a host (e.g., host 208 previously described in connection with FIG. 2) can have a different respective logical address associated with all but one of the plurality of groups of memory cells that have data stored therein (e.g., one of the groups of memory cells that has data stored therein does not have a logical address associated therewith), as previously described herein. For instance, in the example shown in table 330-1 in FIG. 3A, the first group of memory cells (e.g., the group with a physical address of 0) has a logical address of 0, the second group of memory cells (e.g., the group with a physical address of 1) has a logical address of 1, the third group of memory cells (e.g., the group with a physical address of 2) has a logical address of 2, the fifth group of memory cells (e.g., the group with a physical address of 4) has a logical address of 3, the sixth group of memory cells (e.g., the group with a physical address of 5) has a logical address of 4, the seventh group of memory cells (e.g., the group with a physical address of 6) has a logical address of 5, the eighth group of memory cells (e.g., the group with a physical address of 7) has a logical address of 6, and the fourth group of memory cells (e.g., the group with a physical address of 3) is the group that does not have a logical address.

Further, the host may not have a logical address associated with the group of memory cells of the memory device that does not have data stored therein. For instance, in the example shown in table 330-1 in FIG. 3A, the ninth group of memory cells (e.g., the spare group with a physical address of 8) does not have a logical address.

The controller can determine that one of the plurality of groups of memory cells of the memory device is a bad group, as previously described herein. For instance, in the example shown in table 330-1 in FIG. 3A, the third group of memory cells (e.g., the group with a physical address of 2) is determined to be a bad group.

Upon determining the third group of memory cells is a bad group, the controller can recover the data stored in the third group, and program the recovered data to the spare group, as previously described herein. For instance, the controller can program the data recovered from the third group to the ninth group (e.g., the group with the physical address of 8). Further, the controller can map the logical address associated with the third (e.g., bad) group of memory cells to the physical address of the group to which the recovered data was programmed, as previously described herein. For instance, the controller can map logical address 2 to physical address 8, as shown in table 330-2 illustrated in FIG. 3B.

Further, the controller can retire the third (e.g. bad) group of memory cells, as previously described herein. For instance, the third group of memory cells (e.g., the group with a physical address of 2) no longer has a logical address associated therewith, as shown in table 330-2 illustrated in FIG. 3B.

The controller can then copy the data stored in one of the plurality of groups of memory cells to another one of the plurality of groups of memory cells that has data stored therein (e.g., the group that does not have a logical address associated therewith), erase the group of memory cells from which the data was copied, and map the logical address associated with the group of memory cells from which the data was copied to the group of memory cells to which the data is copied, as previously described herein. For instance, in the example shown in table 330-3 illustrated in FIG. 3C, the data stored in the second group of memory cells (e.g., the group with a physical address of 1) is copied to the fourth group of memory cells (e.g., the group with a physical address of 3), the second group of memory cells is erased, and the logical address 1 is mapped to physical address 3, such that the second group of memory cells no longer has a logical address associated therewith.

This erased group of memory cells can become the spare group for use in a subsequent maintenance operation and/or bad group retirement, as previously described herein. For instance, in the example shown in table 330-3 illustrated in FIG. 3C, the second group of memory cells (e.g., the group with a physical address of 1) has become the spare group.

In an example of such a subsequent maintenance operation, shown in table 330-4 illustrated in FIG. 3D, the data stored in the first group of memory cells (e.g., the group with a physical address of 0) is copied to the second group of memory cells (e.g., the group with a physical address of 1), the first group of memory cells is erased, and the logical address 0 is mapped to the physical address 1, such that the first group of memory cells no longer has a logical address associated therewith and becomes the spare group.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combination of the above embodiments, and other embodiments not specifically described herein will be apparent to those of ordinary skill in the art upon reviewing the above description. The scope of a number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
a memory having a plurality of groups of memory cells, wherein:
one of the plurality of groups of memory cells does not have data stored therein; and
all other ones of the plurality of groups of memory cells have data stored therein; and
a controller coupled to the memory and having circuitry configured to:
determine one of the plurality of groups of memory cells that has data stored therein is a bad group of memory cells;
recover the data stored in the bad group of memory cells;
program the recovered data to the one of the plurality of groups of memory cells that does not have data stored therein; and
retire the bad group of memory cells.

2. The apparatus of claim 1, wherein the one of the plurality of groups of memory cells that does not have data stored therein is addressable.

3. The apparatus of claim 1, wherein the circuitry is configured to map a logical address associated with the bad group of memory cells to a physical address associated with the one of the plurality of groups of memory cells to which the recovered data was programmed.

4. The apparatus of claim 1, wherein the circuitry is configured to determine the bad group of memory cells during a scrub operation performed on the memory.

5. The apparatus of claim 1, wherein the memory cells of the plurality of groups are ferroelectric memory cells.

6. The apparatus of claim 1, wherein the groups of memory cells are pages of memory cells.

7. The apparatus of claim 6, wherein the pages of memory cells are physical pages of memory cells.

8. A method of operating memory, comprising:
determining, by a controller coupled to a memory, one of a plurality of groups of memory cells of the memory is a bad group of memory cells;
recovering, by the controller, data stored in the bad group of memory cells;
programming, by the controller, the recovered data to another one of the plurality of groups of memory cells that does not have data stored therein;
retiring, by the controller, the bad group of memory cells; and
mapping, by the controller, a logical address associated with the bad group of memory cells to a physical address associated with the one of the plurality of groups of memory cells to which the recovered data was programmed.

9. The method of claim 8, wherein the method includes recovering the data stored in the bad group of memory cells by performing an error correction operation on the data stored in the bad group of memory cells.

10. The method of claim 8, wherein the method includes copying data stored in one of the plurality of groups of memory cells to another one of the plurality of groups of memory cells that has data stored therein.

11. The method of claim 10, wherein the method includes erasing the one of the plurality of groups of memory cells from which the data was copied.

12. The method of claim 8, wherein the method includes disabling on-die wear leveling operations in the memory.

13. The method of claim 8, wherein the method includes disabling random data scrambling operations in the memory.

14. The method of claim 8, wherein retiring the bad group of memory cells comprises storing no data in the bad group of memory cells.

15. A system, comprising:
a host; and
a memory device, wherein the memory device includes:
a memory having a plurality of groups of memory cells, wherein:
one of the plurality of groups of memory cells does not have data stored therein;
all other ones of the plurality of groups of memory cells have data stored therein; and
the memory device has a different respective physical address associated with each respective one of the plurality of groups of memory cells; and
a controller coupled to the memory and having circuitry configured to:
determine one of the plurality of groups of memory cells that has data stored therein is a bad group of memory cells;
recover the data stored in the bad group of memory cells;
program the recovered data to the one of the plurality of groups of memory cells that does not have data stored therein; and
map a logical address of the host associated with the bad group of memory cells to the physical address associated with the one of the plurality of groups of memory cells to which the recovered data was programmed.

16. The system of claim 15, wherein the circuitry is configured to retire the bad group of memory cells.

17. The system of claim 15, wherein the physical address associated with each respective one of the plurality of groups of memory cells corresponds to a different pin of the memory.

18. The system of claim 15, wherein the host has a different respective logical address associated with all but one of the plurality of groups of memory cells that have data stored therein.

19. The system of claim 15, wherein the host does not have a logical address associated with the one of the plurality of groups of memory cells that does not have data stored therein.

20. The system of claim 15, wherein the bad group of memory cells is a group of memory cells that is not reliable for storing or retrieving data.
